(19) United States
(12) Patent Application Publication
(10) Pub. No.: US 2012/0276407 A1
(43) Pub. Date: Nov. 1, 2012

(54) PROCESS FOR SURFACE TREATING IRON-BASED ALLOY AND ARTICLE

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); YING-YING WANG, Shenzhen City (CN)

(73) Assignees: HON HAI PRECISION INDUSTRY CO., LTD., Tu Cheng (TW); HONG FU JIN PRECISION INDUSTRY (ShenZhen) CO., LTD., Shenzhen City (CN)

(21) Appl. No.: 13/217,933

(22) Filed: Aug. 25, 2011

(30) Foreign Application Priority Data
Apr. 27, 2011 (CN) 201110106350.2

(51) Int. Cl. B32B 15/04; B32B 18/00; C23C 14/34

(52) U.S. Cl. 428/623; 204/192.15

(57) ABSTRACT

A process for surface treating iron-based alloy includes providing a substrate made of iron-based alloy. A stainless steel layer is then formed on the substrate by sputtering. A silicon-oxygen-nitrogen layer is formed on the stainless steel layer by sputtering. A boron-nitrogen layer is next formed on the silicon-oxygen-nitrogen layer by sputtering.

### CROSS-REFERENCE TO RELATED APPLICATIONS

This application is related to co-pending U.S. patent applications (Attorney Docket No. US39243 and US39244, each entitled “PROCESS FOR SURFACE TREATING IRON-BASED ALLOY AND ARTICLE”, each invented by Chang et al. These applications have the same assignee as the present application. The above-identified applications are incorporated herein by reference.

### BACKGROUND

1. Technical Field

The disclosure generally relates to a process for surface treating iron-based alloy, and articles made of iron-based alloy treated by the process.

2. Description of Related Art

Iron-based alloy articles, such as dies are often subjected to oxidation when used in high temperatures. Oxide films resulting from oxidation can damage the quality of the surfaces of the articles. Furthermore, during repeated use, the oxide films can break off, exposing an underneath iron-based alloy substrate. The exposed iron-based alloy substrate is further subjected to oxidation. Thus, the service life of the articles may be reduced.

Therefore, there is room for improvement within the art.

### BRIEF DESCRIPTION OF THE FIGURES

Many aspects of the coated article can be better understood with reference to the following figures. The components in the figures are not necessarily drawn to scale, the emphasis instead being placed upon clearly illustrating the principles of the exemplary process for the surface treating of iron-based alloy and articles made of iron-based alloy treated by the process. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary article treated in accordance with the present process.

FIG. 2 is a schematic view of a vacuum sputtering machine for processing the exemplary article shown in FIG. 1.

### DETAILED DESCRIPTION

An exemplary process for the surface treatment of iron-based alloy may include the following steps:

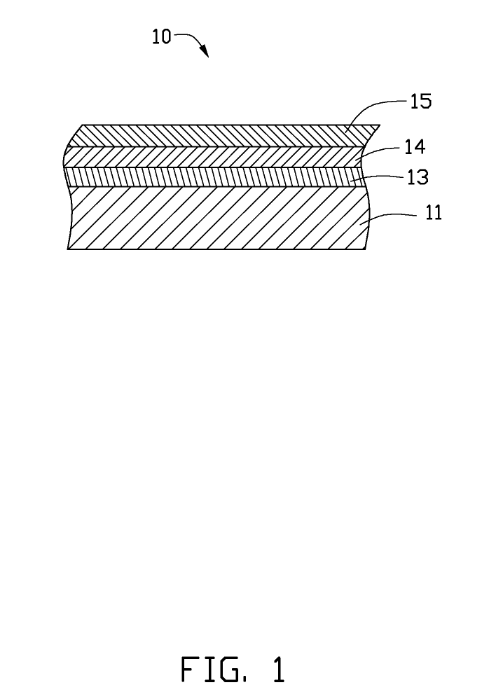

Referring to FIG. 1, a substrate 11 is provided. The substrate 11 is made of an iron-based alloy, such as cutlery steel, die steel, or gauge steel.

The substrate 11 is pretreated. The substrate 11 is cleaned with a solution (e.g., alcohol or acetone) in an ultrasonic cleaner, to remove impurities such as grease or dirt from the substrate 11. Then, the substrate 11 is dried.

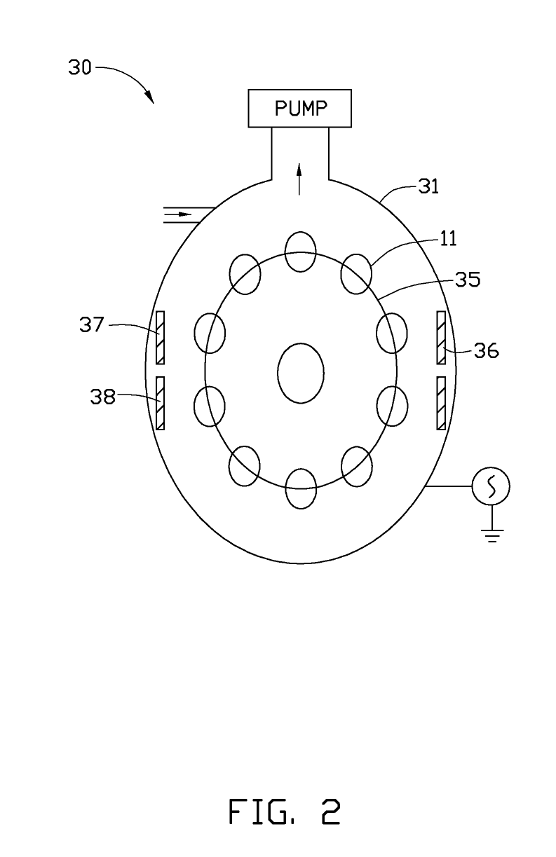

The substrate 11 is plasma cleaned. Referring to FIG. 2, the substrate 11 may be held on a rotating bracket 35 in the vacuum chamber 31 of a vacuum sputtering machine 30. In this exemplary, the vacuum sputtering machine 30 is a DC magnetron sputtering machine. The vacuum chamber 31 is fixed with a stainless steel target 36, a silicon target 37, and a boron target 38 therein. The vacuum chamber 31 is then evacuated to a vacuum level of about 3×10⁻⁵ torr-6×10⁻⁵ torr and maintains the same vacuum level throughout the following steps. Argon (Ar, having a purity of about 99.999%) is fed into the vacuum chamber 31 at a flow rate of about 100 standard-state cubic centimeters per minute (sccm) to 400 sccm. A bias voltage of about −200 V to about −400 V is applied to the substrate 11. Ar is ionized to plasma. The plasma then strikes the surface of the substrate 11 to clean the surface of the substrate 11 further. The plasma cleaning of the substrate 11 may take about 3 minutes (min) to 20 min. The plasma cleaning process enhances the bond between the substrate 11 and a subsequently formed layer. The stainless steel target 36, silicon target 37, and boron target 38 are unaffected by the plasma cleaning process.

A stainless steel layer 13 is formed on the pretreated substrate 11 by vacuum sputtering. Sputtering of the stainless steel layer 13 is implemented in the vacuum chamber 31. The internal temperature of the vacuum chamber 31 may be controlled at about 20° C.-200° C. The flow rate of the argon is adjusted to be about 100 sccm-300 sccm. The bias voltage applied to the substrate 11 is adjusted in a range between about −100 V and about −300 V. About 8 kW-12 kW of power is applied to the stainless steel target 36, depositing the stainless steel layer 13 on the substrate 11. The deposition of the stainless steel layer 13 may take about 5 min-20 min

A silicon-oxygen-nitrogen (SiON) layer 14 is directly formed on the stainless steel layer 13 by vacuum sputtering. Sputtering of the SiON layer 14 is implemented in the vacuum chamber 31. The stainless steel target 36 is switched off. The internal temperature of the vacuum chamber 31 may be controlled at about 20° C.-200° C. Argon, oxygen and nitrogen are simultaneously fed into the vacuum chamber 31, with the argon acting as a sputtering gas and the oxygen and nitrogen acting as reaction gases. The flow rate of the argon is about 100 sccm-300 sccm. The flow rates of oxygen and nitrogen both are about 20 sccm-300 sccm. A bias voltage of about −100 V to about −300 V may be applied to the substrate 11. About 8 kW-12 kW of power is applied to the silicon target 37, depositing the SiON layer 14 on the stainless steel layer 13. The deposition of the SiON layer 14 may take about 10 min-40 min.

A boron-nitrogen (BN) layer 15 is then directly formed on the SiON layer 14 by vacuum sputtering. Sputtering of the BN layer 15 is implemented in the vacuum chamber 31. The silicon target 37 is switched off. The internal temperature of the vacuum chamber 31 may be controlled at about 20° C.-200° C. Argon and nitrogen are simultaneously fed into the vacuum chamber 31, with the argon acting as a sputtering gas and the nitrogen acting as a reaction gas. The flow rate of argon is about 100 sccm-300 sccm. The flow rate of nitrogen is about 20 sccm-200 sccm. A bias voltage of about −100 V to about −300 V may be applied to the substrate 11. About 10 kW-13 kW of power is applied to the boron target 38, depositing the BN layer 15 on the SiON layer 14. The deposition of the BN layer 15 may take about 10 min-60 min

FIG. 1 shows a cross-section of an exemplary article 10 made of iron-based alloy and processed by the surface treatment process described above. The article 10 includes the substrate 11 having the stainless steel layer 13, the SiON layer 14, and the BN layer 15 formed thereon, and in that order. The thickness of the stainless steel layer 13 may be about 20 nm-50 nm. The thickness of the SiON layer 14 may be about 80 nm-150 nm. The thickness of the BN layer 15 may be about 100 nm-200 nm.

The stainless steel layer 13, which has a similar composition with the substrate 11, has a high bonding force with the substrate 11. The SiON layer 14 has a high density and can prevent oxygen from entering in the SiON layer 14 thus protecting the substrate 11 from oxidation. The BN layer 15 has a good lubricity. Thus, when the article 10 used as a mold, the mold can be easily separated from molded articles.

### EXAMPLES

Specific examples of the present disclosure are described as follows. The pretreatment in these specific examples may be substantially the same as described above so it is not described here again. The specific examples mainly emphasize the different process parameters of the process for the surface treatment of iron-based alloy.

### Example 1

The substrate 11 is made of a S316 type die steel. The vacuum chamber 31 maintains a vacuum level of about 3×10⁻⁵ torr.

Plasma cleaning the substrate 11: the flow rate of argon is 200 sccm; a bias voltage of −300 V is applied to the substrate 11; the plasma cleaning of the substrate 11 takes 5 min.

Sputtering to form stainless steel layer 13 on the substrate 11: the flow rate of argon is 150 sccm; the internal temperature of the vacuum chamber 31 is 30° C.; a bias voltage of −150 V is applied to the substrate 11; about 8 kW of power is applied to the stainless steel target 36; sputtering of the stainless steel layer 13 takes 6 min; the stainless steel layer 13 has a thickness of 25 nm.

Sputtering to form SiON layer 14 on the stainless steel layer 13: the flow rate of argon is 150 sccm, the flow rate of nitrogen is 300 sccm, the flow rate of oxygen is 100 sccm; the internal temperature of the vacuum chamber 31 is 30° C.; a bias voltage of −150 V is applied to the substrate 11; about 8 kW of power is applied to the silicon target 37; sputtering of the SiON layer 14 takes 15 min; the SiON layer 14 has a thickness of about 100 nm.

Sputtering to form BN layer 15 on the SiON layer 14: the flow rate of argon is 150 sccm; the flow rate of nitrogen is 40 sccm; the internal temperature of the vacuum chamber 31 is 30° C.; a bias voltage of −150 V is applied to the substrate 11; about 10 kW of power is applied to the boron target 38; sputtering of the BN layer 15 takes 20 min; the BN layer 15 has a thickness of 120 nm.

### Example 2

The substrate 11 is made of a H11 type die steel. The vacuum chamber 31 maintains a vacuum level of about 3×10⁻⁵ torr.

Plasma cleaning the substrate 11: the flow rate of argon is 300 sccm; a bias voltage of −200 V is applied to the substrate 11; the plasma cleaning of the substrate 11 takes 10 min.

Sputtering to form stainless steel layer 13 on the substrate 11: the flow rate of argon is 200 sccm; the internal temperature of the vacuum chamber 31 is 100° C.; a bias voltage of −200 V is applied to the substrate 11; about 11 kW of power is applied to the stainless steel target 36; sputtering of the stainless steel layer 13 takes 15 min; the stainless steel layer 13 has a thickness of 40 nm.

Sputtering to form SiON layer 14 on the stainless steel layer 13: the flow rate of argon is 200 sccm, the flow rate of nitrogen is 200 sccm, the flow rate of oxygen is 150 sccm; the internal temperature of the vacuum chamber 31 is 100° C.; a bias voltage of −200 V is applied to the substrate 11; about 11 kW of power is applied to the silicon target 37; sputtering of the SiON layer 14 takes 20 min; the SiON layer 14 has a thickness of about 120 nm.

Sputtering to form BN layer 15 on the SiON layer 14: the flow rate of argon is 150 sccm; the flow rate of nitrogen is 60 sccm; the internal temperature of the vacuum chamber 31 is 100° C.; a bias voltage of −200 V is applied to the substrate 11; about 13 kW of power is applied to the boron target 38; sputtering of the BN layer 15 takes 40 min; the BN layer 15 has a thickness of 140 nm.

### Example 3

The substrate 11 is made of a P20 type die steel. The vacuum chamber 31 maintains a vacuum level of about 3×10⁻⁵ torr.

Plasma cleaning the substrate 11: the flow rate of argon is 300 sccm; a bias voltage of −200 V is applied to the substrate 11; plasma cleaning of the substrate 11 takes 10 min.

Sputtering to form stainless steel layer 13 on the substrate 11: the flow rate of argon is 200 sccm; the internal temperature of the vacuum chamber 31 is 150° C.; a bias voltage of −200 V is applied to the substrate 11; about 10 kW of power is applied to the stainless steel target 36; sputtering of the stainless steel layer 13 takes 20 min; the stainless steel layer 13 has a thickness of 50 nm.

Sputtering to form SiON layer 14 on the stainless steel layer 13: the flow rate of argon is 200 sccm, the flow rate of nitrogen is 250 sccm, the flow rate of oxygen is 100 sccm; the internal temperature of the vacuum chamber 31 is 150° C.; a bias voltage of −200 V is applied to the substrate 11; about 10 kW of power is applied to the silicon target 37; sputtering of the SiON layer 14 takes 60 min; the SiON layer 14 has a thickness of about 150 nm.

Sputtering to form BN layer 15 on the SiON layer 14: the flow rate of argon is 200 sccm; the flow rate of nitrogen is 200 sccm; the internal temperature of the vacuum chamber 31 is 150° C.; a bias voltage of −200 V is applied to the substrate 11; about 11 kW of power is applied to the boron target 38; sputtering of the BN layer 15 takes 60 min; the BN layer 15 has a thickness of 160 nm.

An oxidation test at high temperature was applied to the samples created by examples 1-3. The test was carried out in an air atmosphere. The samples were retained in a high temperature oven for about 1 hour and then were removed. The oven maintained an internal temperature of about 800° C. Neither oxidation nor peeling was found with the samples created by examples 1-3.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A process for surface treating iron-based alloy, the process comprising the following steps of:
providing a substrate made of iron-based alloy;
forming a stainless steel layer on the substrate by sputtering;
forming a silicon-oxygen-nitrogen layer on the stainless steel layer by sputtering; and
forming a boron-nitrogen layer on the silicon-oxygen-nitrogen layer by sputtering.

2. The process as claimed in claim 1, wherein sputtering of the stainless steel layer uses argon at a flow rate of about 100 sccm-300 sccm as a puttering gas; uses a stainless steel target and applies about 8 kW-12 kW of power to the stainless steel target; applies a bias voltage of about −100 V to about −300 V to the substrate; sputtering of the stainless steel layer is conducted at a temperature of about 20° C.-200° C. and takes about 5 min-20 min.

3. The process as claimed in claim 1, wherein sputtering of the silicon-oxygen-nitrogen layer uses argon at a flow rate of about 100 sccm-300 sccm as a puttering gas; uses nitrogen and oxygen each at a flow rate of about 20 sccm-300 sccm as reaction gases, uses a silicon target and applies about 8 kW-12 kW of power to the silicon target; applies a bias voltage of about −100 V to about −300 V to the substrate;
sputtering of the silicon-oxygen-nitrogen layer is conducted at a temperature of about 20° C.-200° C. and takes about 10 min-40 min.

4. The process as claimed in claim 1, wherein sputtering of the boron-nitrogen layer uses argon at a flow rate of about 100 sccm-300 sccm as a puttering gas; uses nitrogen at a flow rate of about 20 sccm-200 sccm as a reaction gas, uses a boron target and applies about 10 kW-13 kW of power to the boron target; applies a bias voltage of about −100 V to about −300 V to the substrate; sputtering of the boron-nitrogen layer is conducted at a temperature of about 20° C.-200° C. and takes about 10 min-60 min.

5. The process as claimed in claim 1, further comprising a step of plasma cleaning the substrate, before forming the stainless steel layer.

6. An article, comprising:
a substrate made of iron-based alloy;
a stainless steel layer formed on the substrate;
a silicon-oxygen-nitrogen layer formed on the stainless steel layer; and
a boron-nitrogen layer formed on the silicon-oxygen-nitrogen layer.

7. The article as claimed in claim 6, wherein the stainless steel layer has a thickness of about 20 nm-50 nm.

8. The article as claimed in claim 6, wherein the silicon-oxygen-nitrogen layer has a thickness of about 80 nm-150 nm.

9. The article as claimed in claim 6, wherein the boron-nitrogen layer has a thickness of about 100 nm-120 nm.

10. The article as claimed in claim 6, wherein the stainless steel layer, silicon-oxygen-nitrogen layer, and boron-nitrogen all are formed by sputtering.

11. The article as claimed in claim 6, wherein the substrate is made of a material selected from the group consisting of cutlery steel, die steel, and gauge steel.
